(19) United States
(12) Patent Application Publication
(10) Pub. No.: US 2025/0234686 A1
(43) Pub. Date: Jul. 17, 2025

(54) DISPLAY PANEL

(71) Applicant: AUO Corporation, Hsinchu City (TW)

(72) Inventor: Tzu-Chin Huang, Hsinchu City (TW)

(73) Assignee: AUO Corporation, Hsinchu City (TW)

(21) Appl. No.: 18/811,814

(22) Filed: Aug. 22, 2024

(30) Foreign Application Priority Data
Jan. 15, 2024 (TW) 113101492

(51) Int. Cl. H01L 33/50; H01L 25/075

(52) U.S. Cl. CPC H10H 20/8512; H01L 25/0753

(57) ABSTRACT

A display panel including multiple pixels is disclosed, where each pixel includes a first substrate, a second substrate, a first light-emitting element, a first color conversion layer, and a second color conversion layer. The first light-emitting element is disposed on a first region of the first substrate. The first color conversion layer is disposed on the first region of the first substrate, and wraps the first light-emitting element. The second color conversion layer is disposed on the second substrate, and corresponds to at least a second region of the first substrate. A spare space is present on the second region of the first substrate, and a size of the spare space is larger than or equal to a volume of the first light-emitting element.

### CROSS-REFERENCE TO RELATED APPLICATION

This application claims the priority benefit of Taiwan application serial no. 113101492, filed on Jan. 15, 2024. The entirety of the above-mentioned patent application is hereby incorporated by reference herein and made a part of this specification.

### BACKGROUND

### Technical Field

This disclosure relates to a display panel.

### Description of Related Art

Traditionally, in light-emitting diode (LED) displays employing color conversion technology, to achieve a high color conversion efficiency, the color conversion layer is generally fabricated on the lower substrate, wrapping the light-emitting diodes. However, in the event of LED damage, it becomes challenging to repair the pixel. Conversely, if the color conversion layer is fabricated on the upper substrate for the purpose of repairability, the color conversion efficiency is consequently diminished.

### SUMMARY

The disclosure provides a display panel with high color conversion rate, capable of repairing damaged light-emitting diodes.

According to an embodiment of the disclosure, a display panel is provided, including multiple pixels. Each of the pixels including a first substrate, a second substrate, a first light-emitting element, a first color conversion layer, and a second color conversion layer. The first substrate has a first surface, and the first surface includes a first region and a second region. The second substrate has a second surface facing the first surface. The first light-emitting element is disposed on the first region of the first surface. The first color conversion layer is disposed on the first region of the first surface. The first light-emitting element is located between the first surface and the first color conversion layer, and the first color conversion layer wraps the first light-emitting element. The second color conversion layer is disposed on the second surface and corresponds to at least the second region of the first surface. A spare space is present on the second region of the first surface, and a size of the spare space is greater than or equal to a volume of the first light-emitting element.

Based on the above, the multiple pixels of the display panel provided by the embodiments of the disclosure are configured with a first light-emitting element and a first color conversion layer that wraps the first light-emitting element. Accordingly, the first light-emitting element can have good color conversion rate. In addition, the pixels are also configured with a spare space and a second color conversion layer corresponding to the spare space. When the first light-emitting element is damaged, another light-emitting element can be configured in the spare space to replace the first light-emitting element. Accordingly, the display panel can be repaired more easily.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate example embodiments of the disclosure and, together with the description, serve to explain the principles of the disclosure.

FIG. 1A is a schematic diagram of a display panel according to an embodiment of the disclosure.

FIG. 1B is a schematic diagram of a display panel according to an embodiment of the disclosure.

FIG. 2 is a schematic diagram of a display panel according to an embodiment of the disclosure.

FIG. 3 is a schematic diagram of a display panel according to an embodiment of the disclosure.

### DESCRIPTION OF THE EMBODIMENTS

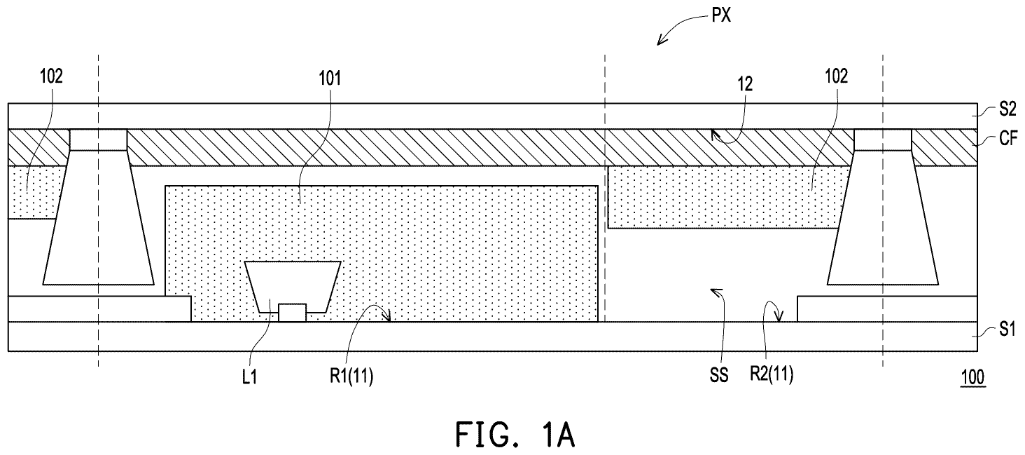

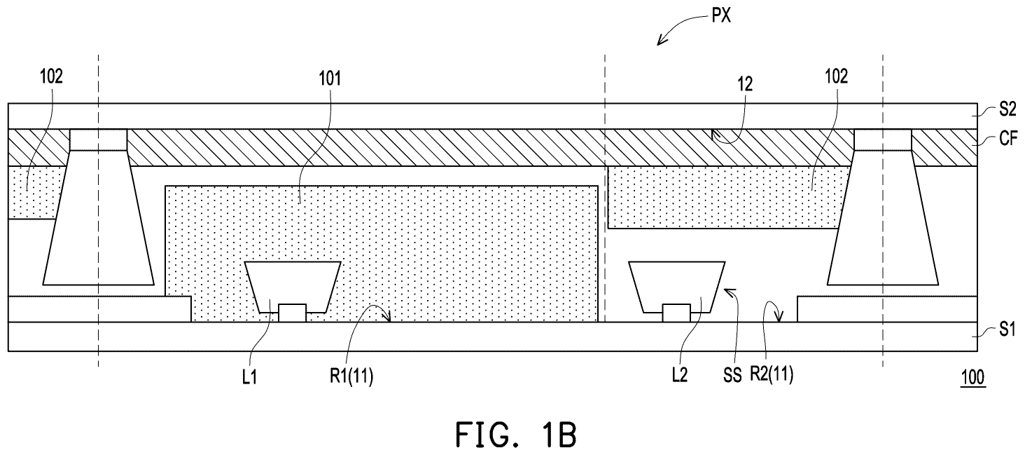

FIG. 1A is a schematic diagram of a display panel according to an embodiment of the disclosure. A display panel 100 includes multiple pixels PX, and each pixel PX includes a first substrate S1, a second substrate S2, a first light-emitting element L1, a first color conversion layer 101, and a second color conversion layer 102. The first substrate S1 has a first surface 11, and the first surface 11 includes a first region R1 and a second region R2. The second substrate S2 has a second surface 12 facing the first surface 11. The first light-emitting element L1 is disposed on the first region R1 of the first surface 11. The first color conversion layer 101 is disposed on the first region R1 of the first surface 11. The first light-emitting element L1 is located between the first surface 11 and the first color conversion layer 101, and the first color conversion layer 101 wraps the first light-emitting element L1. The second color conversion layer 102 is disposed on the second surface 12, and the vertical projection of the second color conversion layer 102 on the first substrate S1 overlaps the second region R2 of the first surface 11. A spare space SS is present on the second region R2 of the first surface 11, and the size of the spare space SS is greater than or equal to the volume of the first light-emitting element L1.

The first light-emitting element L1 may be, for example, a blue light-emitting diode for emitting blue light. After the blue light is absorbed by the quantum dots of the first color conversion layer 101, an energy level transition occurs, generating light with a longer wavelength than the blue light, such as red light and green light. The first color conversion layer 101 is configured to wrap the first light-emitting element L1 to improve the color conversion rate. In some embodiments, the display panel 100 may also include a filter layer CF. When the first color conversion layer 101 is used to generate red light, the filter layer CF is a red filter layer. When the first color conversion layer 101 is used to generate green light, the filter layer CF is a green filter layer.

Please continue to refer to FIG. 1B. The spare space SS can be used for the configuration of the second light-emitting element L2, where the second light-emitting element L2 has the same optical properties as the first light-emitting element L1. For example, the second light-emitting element L2 and the first light-emitting element L1 are both blue light-emitting diodes. The blue light emitted by the second light-emitting element L2 can be used by the quantum dots in the second color conversion layer 102 to generate light with a longer wavelength than the blue light, such as red light and green light.

Compared with the display panel that only has the first light-emitting element L1 and the first color conversion layer 101 covering the first light-emitting element L1, but does not have the second color conversion layer 102 and the corresponding spare space SS according to the conventional technology, in the display panel 100 shown in FIG. 1A, when the first light-emitting element L1 is damaged and cannot be easily replaced due to being wrapped by the first color conversion layer 101, the second light-emitting element L2 can be further configured, wherein the second light-emitting element L2 and the second color conversion layer 102 have a function of replacing the first light-emitting element L1 and the first color conversion layer 101.

In order to fully illustrate various implementation aspects of the disclosure, other embodiments of the disclosure are described below. It should be noted here that the following embodiments follow the reference numerals and part of the content of the previous embodiments, where the same reference numerals are used to represent the same or similar elements, and descriptions of the same technical content are omitted. For descriptions of omitted parts, reference may be made to the foregoing embodiments and are not repeated in the following embodiments.

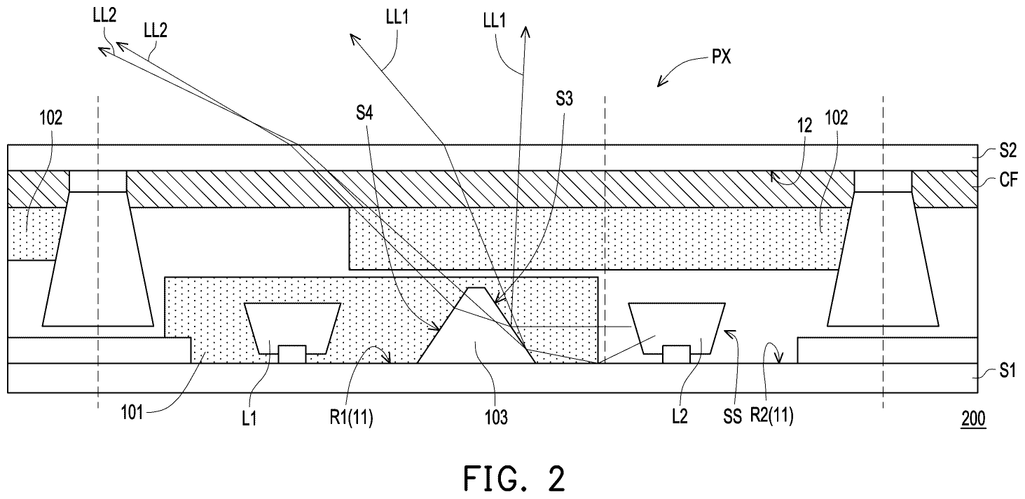

FIG. 2 is a schematic diagram of a display panel according to an embodiment of the disclosure. A display panel 200 includes multiple pixels PX, and each pixel PX includes a first substrate S1, a second substrate S2, a first light-emitting element L1, a first color conversion layer 101, a second color conversion layer 102, and a light guide element 103. The first substrate S1 has a first surface 11, and the first surface 11 includes a first region R1 and a second region R2. The second substrate S2 has a second surface 12 facing the first surface 11.

The first light-emitting element L1 and the light guide element 103 are disposed on the first region R1 of the first surface 11. The first color conversion layer 101 is disposed on the first region R1 of the first surface 11. The first light-emitting element L1 and the light guide element 103 are located between the first surface 11 and the first color conversion layer 101, and the first color conversion layer 101 wraps the first light-emitting element L1 and the light guide element 103.

The second color conversion layer 102 is disposed on the second surface 12, and the vertical projection of the second color conversion layer 102 on the first substrate S1 overlaps the first region R1 and the second region R2 of the first surface 11. A spare space SS is present on the second region R2 of the first surface 11, and the size of the spare space SS is greater than or equal to the volume of the first light-emitting element L1.

The spare space SS can be used for the configuration of the second light-emitting element L2 with the same optical properties as the first light-emitting element L1 when the first light-emitting element L1 is damaged. Compared with the display panel 100 shown in FIG. 1A and FIG. 1B, the display panel 200 configured with the light guide element 103 can prevent the light emitted by the second light-emitting element L2 from traveling toward the first light-emitting element L1 and being absorbed by the first light-emitting element L1, which reduces the luminous intensity of display panel 200.

The light guide element 103 is disposed between the first light-emitting element L1 and the spare space SS, and has a light guide surface S3 facing the spare space SS and a light guide surface S4 facing the first light-emitting element L1. The angle between the light guide surface S3 and the first surface 11 and the angle between the light guide surface S4 and the first surface 11 are greater than 0 degrees and less than 90 degrees. The light guide element 103 may include a high reflectivity material, and/or the refractive index of the light guide element 103 may be lower than the first color conversion layer 101, and specifically may include a relatively low refractive index material of a silica-oxide-based material doped with air particles.

In this embodiment, the first color conversion layer 101 completely wraps the light guide element 103, and the vertical projection of the first color conversion layer 101 on the first surface 11 completely overlaps the vertical projections of the light guide surface S3 and the light guide surface S4 on the first surface 11. However, the disclosure is not limited thereto. In some embodiments, the first color conversion layer 101 can partially wrap the light guide element 103, or not wrap the light guide element 103 at all.

In this embodiment, the light emitted by the first light-emitting element L1 can be reflected by the light guide surface S4, and then pass through the first color conversion layer 101 and the second color conversion layer 102 in sequence. Similarly, when the spare space SS is used for configuration of the second light-emitting element L2, the light emitted by the second light-emitting element L2 can be reflected by the light guide surface S3, and then pass through the first color conversion layer 101 and the second color conversion layer 102 in sequence.

Accordingly, the light field of the display panel 200 can be optimized. Moreover, since the vertical projection of the first color conversion layer 101 on the first surface 11 completely overlaps the vertical projection of the light guide surface S3 on the first surface 11, the light emitted by the second light-emitting element L2 can be first color-converted by the first color conversion layer 101 before it is reflected by the light guide surface S3, thus improving the color conversion rate.

It should be noted that since the vertical projection of the second color conversion layer 102 on the first surface 11 completely overlaps the vertical projection of the light guide surface S3 on the first surface 11, light LL1 reflected by the light guide surface S3 can pass through the first color conversion layer 101 wrapping the light guide element 103, and then pass through the second color conversion layer 102 to improve the color conversion rate. Furthermore, since the vertical projection of the second color conversion layer 102 on the first surface 11 completely overlaps the vertical projection of the light guide surface S4 on the first surface 11, light LL2 passing through the light guide surface S3 and the light guide surface S4 can pass through the first color conversion layer 101 wrapping the light guide element 103, and then pass through the second color conversion layer 102 to improve the color conversion rate.

In an embodiment not shown, the vertical projection of the second color conversion layer 102 on the first surface 11 completely overlaps the vertical projections of the light guide surface S3, the light guide surface S4, and the first light-emitting element L1 on the first surface 11. When the display panel 200 is not configured with the second light-emitting element L2, the second color conversion layer 102 overlapping the first light-emitting element L1 may improve the color conversion rate of the first light-emitting element L1.

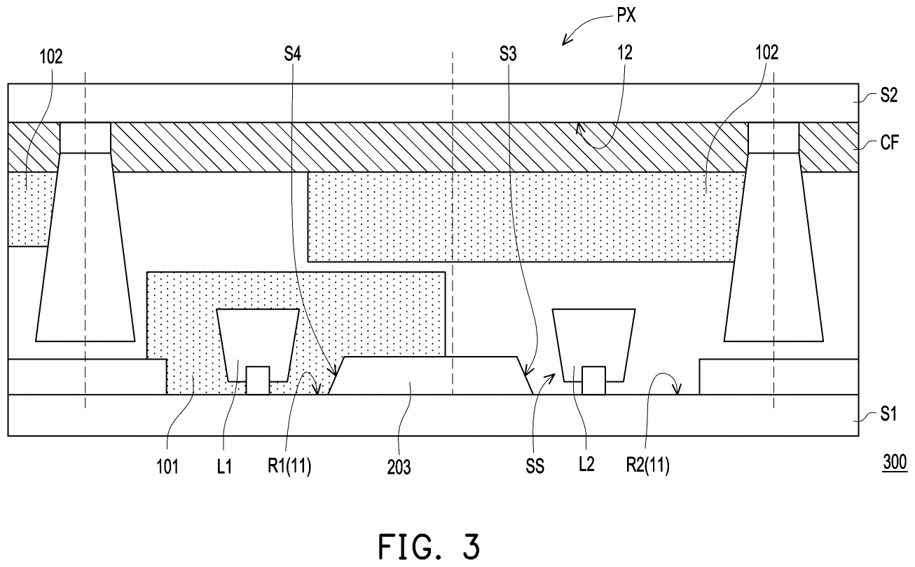

FIG. 3 is a schematic diagram of a display panel according to an embodiment of the disclosure. A display panel 300 includes multiple pixels PX, and each pixel PX includes a first substrate S1, a second substrate S2, a first light-emitting element L1, a first color conversion layer 101, a second color conversion layer 102, and a light guide element 203. The first substrate S1 has a first surface 11, and the first surface 11 includes a first region R1 and a second region R2. The second substrate S2 has a second surface 12 facing the first surface 11.

The first light-emitting element L1 is disposed on the first region R1 of the first surface 11. The first color conversion layer 101 is disposed on the first region R1 of the first surface 11. The first light-emitting element L1 is located between the first surface 11 and the first color conversion layer 101, and the first color conversion layer 101 wraps the first light-emitting element L1.

The light guide element 203 is partially disposed on the first region R1 of the first surface 11 and partially disposed on the second region R2 of the first surface 11. Part of the light guide element 203 is wrapped by the first color conversion layer 101, and part of the light guide element 203 is exposed from the first color conversion layer 101.

The second color conversion layer 102 is disposed on the second surface 12, and the vertical projection of the second color conversion layer 102 on the first substrate S1 overlaps the first region R1 and the second region R2 of the first surface 11. A spare space SS is present on the second region R2 of the first surface 11, and the size of the spare space SS is greater than or equal to the volume of the first light-emitting element L1.

The spare space SS can be used for the configuration of the second light-emitting element L2 with the same optical properties as the first light-emitting element L1 when the first light-emitting element L1 is damaged.

The light guide element 203 is disposed between the first light-emitting element L1 and the spare space SS, and has a light guide surface S3 facing the spare space SS and a light guide surface S4 facing the first light-emitting element L1. The angle between the light guide surface S3 and the first surface 11 and the angle between the light guide surface S4 and the first surface 11 are greater than 0 degrees and less than 90 degrees.

In this embodiment, the first color conversion layer 101 partially wraps the light guide element 203. The vertical projection of the first color conversion layer 101 on the first surface 11 overlaps the vertical projection of the light guide surface S4 on the first surface 11, but does not overlap the vertical projection of the light guide surface S3 on the first surface 11. However, the disclosure is not limited thereto. In some embodiments, the first color conversion layer 101 can completely wrap the light guide element 203, or not wrap the light guide element 203 at all.

In this embodiment, the light emitted by the first light-emitting element L1 can be reflected by the light guide surface S4, and then pass through the first color conversion layer 101 and the second color conversion layer 102 in sequence. When the spare space SS is used for configuration of the second light-emitting element L2, the light emitted by the second light-emitting element L2 can be reflected by the light guide surface S3 and then pass through the second color conversion layer 102. Accordingly, the light field of the display panel 300 can be optimized.

In an embodiment not shown, the vertical projection of the second color conversion layer 102 on the first surface 11 completely overlaps the vertical projections of the light guide surface S3, the light guide surface S4, and the first light-emitting element L1 on the first surface 11. When the display panel 300 is not configured with the second light-emitting element L2, the second color conversion layer 102 overlapping the first light-emitting element L1 may improve the color conversion rate of the first light-emitting element L1.

To sum up, the multiple pixels of the display panel provided by the embodiments of the disclosure are configured with a first light-emitting element and a first color conversion layer that wraps the first light-emitting element. Accordingly, the first light-emitting element can have good color conversion rate. In addition, the pixels are also configured with a spare space and a second color conversion layer corresponding to the spare space. When the first light-emitting element is damaged, another light-emitting element (the second light-emitting element) can be configured in the spare space to replace the first light-emitting element and the first color conversion layer with the second light-emitting element and the second color conversion layer. Accordingly, the display panel can be repaired more easily.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A display panel comprising a plurality of pixels, each of the pixels comprising:
a first substrate, having a first surface, the first surface comprising a first region and a second region;
a second substrate, having a second surface facing the first surface;
a first light-emitting element, disposed on the first region of the first surface;
a first color conversion layer, disposed on the first region of the first surface, wherein the first light-emitting element is located between the first surface and the first color conversion layer, and the first color conversion layer wraps the first light-emitting element; and
a second color conversion layer, disposed on the second surface and corresponding to at least the second region of the first surface,
wherein a spare space is present on the second region of the first surface, and a size of the spare space is greater than or equal to a volume of the first light-emitting element.

2. The display panel according to claim 1 further comprising a second light-emitting element disposed in the spare space, wherein the second light-emitting element has same optical properties as the first light-emitting element.

3. The display panel according to claim 1 further comprising a light guide element disposed between the first light-emitting element and the spare space, and having a third surface facing the spare space, wherein the third surface is located between the first surface and the first color conversion layer, and an angle between the third surface and the first surface is greater than 0 degrees and less than 90 degrees.

4. The display panel according to claim 3, wherein a part of the first color conversion layer is located between the light guide element and the spare space.

5. The display panel according to claim 3, wherein a vertical projection of the first color conversion layer on the first surface completely overlaps a vertical projection of the third surface on the first surface.

6. The display panel according to claim 3, wherein the light guide element further has a fourth surface facing the first light-emitting element, and a vertical projection of the first color conversion layer on the first surface completely overlaps a vertical projection of the fourth surface on the first surface.

7. The display panel according to claim 3, wherein the first color conversion layer at least partially wraps the light guide element.

8. The display panel according to claim 3, wherein a vertical projection of the second color conversion layer on the first surface completely overlaps a vertical projection of the third surface on the first surface.

9. The display panel according to claim 3, wherein the light guide element further has a fourth surface facing the first light-emitting element, and a vertical projection of the second color conversion layer on the first surface completely overlaps a vertical projection of the fourth surface on the first surface.

10. The display panel according to claim 9, wherein the vertical projection of the second color conversion layer on the first surface completely overlaps a vertical projection of the first light-emitting element on the first surface.

11. The display panel according to claim 1, wherein the second color conversion layer corresponds to the first region of the first surface.

12. The display panel according to claim 1, wherein the first color conversion layer and the second color conversion layer are disposed separately and are not connected.

13. The display panel according to claim 1, wherein the first light-emitting element is a blue light-emitting diode, and the each of the pixels generates red light or green light.
